(19) United States
(12) Patent Application Publication
(10) Pub. No.: US 2026/0135067 A1
(43) Pub. Date: May 14, 2026

(54) RESONATOR PROBE FOR PLASMA DIAGNOSTICS

(71) Applicant: Applied Materials, Inc., Santa Clara, CA (US)

(72) Inventors: DAVID PETERSON, San Jose, CA (US); KELVIN CHAN, San Ramon, CA (US); SHARIFUL ISLAM BHUIYAN, San Jose, CA (US); YUHUA XIAO, Fremont, CA (US); RAJESH KUMAR PUTTI, Sunnyvale, CA (US); SHUBHAM KIRAN WANI, Santa Clara, CA (US)

(21) Appl. No.: 18/942,302

(22) Filed: Nov. 8, 2024

(51) Int. Cl. H01J 37/32

(52) U.S. Cl. CPC H01J 37/32247; H01J 37/32935

(57) ABSTRACT

Embodiments include a plasma processing apparatus including a chamber with an inner chamber wall. A workpiece support is within the inner chamber wall, the workpiece support for supporting a workpiece in a processing region of the chamber. A resonator probe is coupled to the inner chamber wall. The resonator probe includes an exposed resonator and a buried resonator.

### BACKGROUND

### 1) Field

Embodiments relate to the field of plasma processing and, in particular, to plasma processing chambers including a resonator probe for plasma diagnostics.

### 2) Description of Related Art

Plasma processing is used extensively in the manufacture of many different technologies, such as those in the semiconductor industry, display technologies, microelectromechanical systems (MEMS), and the like. Currently, radio frequency (RF) generated plasmas are most often used. However, plasmas generated with a microwave source allow for denser plasmas and/or plasmas with a high concentration of excited neutral species. Unfortunately, plasmas generated with a microwave source also suffer their own drawbacks.

### SUMMARY

Embodiments include a plasma processing apparatus including a chamber with an inner chamber wall. A workpiece support is within the inner chamber wall, the workpiece support for supporting a workpiece in a processing region of the chamber. A resonator probe is coupled to the inner chamber wall. The resonator probe includes an exposed resonator and a buried resonator.

According to an embodiment, a resonator probe for measuring a temperature and a plasma property in a plasma region of a plasma processing apparatus includes an exposed resonator and a buried resonator.

In an additional embodiment, a method for monitoring a plasma parameter includes providing a resonator probe coupled to an inner chamber wall of a plasma processing apparatus. The resonator probe includes an exposed resonator and a buried resonator. The method also includes measuring a temperature of the resonator probe, and using the measured temperature to correct for temperature effects that can inhibit the measurement of plasma properties.

The above summary does not include an exhaustive list of all embodiments. It is contemplated that all systems and methods are included that can be practiced from all suitable combinations of the various embodiments summarized above, as well as those disclosed in the Detailed Description below and particularly pointed out in the claims filed with the application. Such combinations have particular advantages not specifically recited in the above summary.

### BRIEF DESCRIPTION OF THE DRAWINGS

FIG. 1 is a schematic diagram of a plasma processing tool that includes a modular microwave plasma source, in accordance with an embodiment.

FIG. 2 is a schematic block diagram of a solid state microwave plasma source, in accordance with an embodiment.

FIG. 3 illustrates a plan view of a resonator probe inserted into a plasma processing region of a plasma processing chamber, in accordance with an embodiment of the present disclosure.

FIG. 4A is a plot of microwave source plasma measurements as a function of Watts (W), and FIG. 4B is a plot of resonant frequency as a function of temperature (showing a temperature dependence), in accordance with an embodiment of the present disclosure.

FIGS. 5A-5E illustrate cross-sectional views and plan views of resonator probes or wafers for use in a plasma processing region of a plasma processing chamber, in accordance with an embodiment of the present disclosure.

FIG. 6 illustrates a block diagram of an exemplary computer system that may be used in conjunction with a plasma processing chamber including a resonator probe, in accordance with an embodiment.

### DETAILED DESCRIPTION

A plasma processing chamber including a resonator probe for plasma diagnostics is described in accordance with various embodiments. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Typical microwave plasma systems use a singular, large source of microwave radiation (typically a magnetron) and a transmission path for guiding the microwave radiation from the magnetron to the processing chamber. For typical high power applications in the semiconductor industry, the transmission path is a microwave waveguide. Waveguides are used because outside of a waveguide designed to carry the specific frequency of the microwave source, the microwave power attenuates rapidly with distance. Additional components, such as tuners, couplers, mode transformers, and the like are also required to transmit the microwave radiation to the processing chamber. These components limit the construction to large systems (i.e., at least as large as the sum of the waveguide and associated components), and severely limit the design. As such the geometry of the plasma that may be produced is constrained since the geometry of the plasma resembles the shape of the waveguides.

In such microwave sources, the size of the microwave plasma source is limited to a dimensions that is equal to or larger than half the wave length (i.e., λ/2) of the microwave radiation. The dimensions of the microwave plasma sources can only be in multiples of a half wavelength (i.e., Nλ/2, where N is equal to any positive integer) of the microwave radiation to produce a stable microwave plasma. At 2.45GHz, the wavelength of the microwave is at 12.25 cm in air or vacuum. As such, the dimension of the plasma has to be in multiples of 6.125 cm. Accordingly, the microwave plasma sources are limited to certain symmetrical geometric shape and sizes, and limits where a microwave plasma sources may be used.

Accordingly, it is difficult to match the geometry of the plasma to the geometry of the substrate that is being processed. In particular, it is difficult to create a microwave plasma where the plasma is generated over the entire surface of the wafer of larger substrates (e.g., 300 mm or greater wafers). Some microwave generated plasmas may use a slot line antenna to allow the microwave energy to be spread over an extended surface. However, such systems are complicated, require specific geometry, and are limited in the power density that can be coupled to the plasma.

Furthermore, microwave sources typically generate plasmas that are not highly uniform and/or are not able to have a spatially tunable density. Particularly, the uniformity of the plasma source is dependent on the modes of the standing wave pattern of the microwave with respect to the particular geometry of the microwave cavity or antenna. Thus, the uniformity is determine mainly by the geometry of the design and is not tunable. As the substrates that are being processed continue to increase in size, it becomes increasingly difficult to account for edge effects due to the inability to tune the plasma. Additionally, the inability to tune the plasma limits the ability to modify processing recipes to account for incoming substrate nonuniformity and adjust the plasma density for processing systems in which a nonuniformity is required to compensate for the design of the processing system (e.g., to accommodate the nonuniform radial velocity of the rotating wafers in some processing chambers).

Embodiments include temperature measurement techniques and schemes for temperature compensation of plasma diagnostics using printed microwave resonator probes.

In accordance with one or more embodiments of the present disclosure, a method to measure temperature that is immune to the harsh plasma environment used in semiconductor manufacturing and a scheme to account for temperature effects for printed microwave resonator plasma diagnostics are described. In an embodiment, two resonators with different resonant frequencies are measured simultaneously, where one resonator is exposed to plasma conditions and another is not, while both resonators are approximately the same temperature due to close physical proximity.

To provide context, microwave resonator plasma diagnostics have the potential to be a completely non-invasive and real-time plasma diagnostic used in all plasma based process chambers. Addressing temperature variations in the resonator can be important for obtaining high fidelity measurements. A temperature compensation scheme described herein can also be performed non-invasively and in parallel to a standard measurement technique.

To provide further context, printed microwave resonators are relatively new as a plasma diagnostic, and recent data has shown that temperature compensation can be important for obtaining accurate results. In accordance with one or more embodiments, an approach described herein can be implemented to allow for local temperature measurements without any interference from the harsh plasma environment and improves plasma density measurement accuracy. In one embodiment, immunity to the harsh plasma environment can also improve temperature measurement precision relative to standard temperature measurement techniques.

Advantages for implementing embodiments described herein can include that many temperature measurement techniques are otherwise susceptible to various forms of interference in a plasma processing environment (plasma, RF, chemical, etc.), whereas embodiments described herein can be immune to these effects. No other temperature compensation schemes currently exist for microwave resonator probe diagnostics.

In an embodiment, a microwave resonator can be shielded from the external environment in a multilayer material that includes various ground layers to mitigate the effect of the external environment to be used as a temperature measurement technique. The microwave resonance frequency is measured as a function of known temperature to provide a calibration scheme to convert measured microwave resonant frequency to temperature when inserted into a process environment. The technique can be implemented to provide stable temperature measurements over a large dynamic range and can be immune to the various effects from the external environment.

In an embodiment, two microwave resonators with different resonant frequencies are measured simultaneously, where one resonator is exposed to plasma conditions and another is not exposed, while both resonators are approximately at the same temperature due to close physical proximity, allowing for local temperature compensation to be utilized for plasma diagnostic enhancement.

It is to be appreciated that resonator probes described herein can be implemented for use with a non-pulsed plasma in a variety of arrangements. It is to be appreciated that resonator probes described herein can be implemented for use with a pulsed plasma in a variety of arrangements, including conventional pulsed plasma arrangements based on a magnetron. In other embodiments, resonator probes described herein can be implemented for use with a pulsed plasma based on solid state electronics. An exemplary plasma etch arrangement for use with a resonator probe described herein is described below as an illustrative implementation. For example, the use of solid state electronics instead of a magnetron allows for a significant reduction in the size and the complexity of the plasma source. Particularly, the solid state components are much smaller than the magnetron hardware described above. Additionally, the use of a distributed arrangement employing solid state components allows for the elimination of bulky waveguides needed to transmit the microwave radiation to the processing chamber. Instead, the microwave radiation may be transmitted with coaxial cabling. The elimination of waveguides also allows for the construction of a large area microwave source where the size of the plasma formed is not limited by the size of waveguides. Instead, an array of microwave modules may be constructed in a given pattern that allows for the formation of a plasma that is arbitrarily large (and arbitrarily shaped) to match the shape of any substrate. For example, the applicators of the microwave modules may be arranged on (or partially embedded within) dielectric bodies that are any desired shape, (e.g., symmetric plates, irregular plates, non-planar dielectric bodies, dielectric structures with internal voids, or the like). Furthermore, the cross-sectional shape of the applicators may be chosen so that the array of applicators may be packed together as tightly as possible (i.e., a closed-packed array). Embodiments may also allow for applicators in the array of microwave modules to have non-uniform sizes. As such, the packing efficiency may be improved further.

The use of an array of microwave modules also provides greater flexibility in the ability to locally change the plasma density by independently changing the power settings of each microwave module. This allows for uniformity optimization during plasma processing, such as adjustments made for wafer edge effects, adjustments made for incoming wafer nonuniformity, and the ability to adjust the plasma density for processing systems in which a nonuniformity is needed to compensate for the design of the processing system (e.g., to accommodate the nonuniform radial velocity of the rotating wafers in some processing chambers).

Additional embodiments may also include one or more plasma monitoring sensors. Such embodiments provide a way to measure the density of the plasma (or any other plasma property) locally by each applicator, and to use that measurement as part of a feedback loop to control the power applied to each microwave module. Accordingly, each microwave module may have independent feedback, or a subset of the microwave modules in the array may be grouped in zones of control where the feedback loop controls the subset of microwave modules in the zone.

In addition to the enhanced tuneability of the plasma, the use of individual microwave modules provides a greater power density than currently available plasma sources. For example, microwave modules may allow for a power density that is approximately five or more times greater than typical RF plasma processing systems. For example, typical power into a plasma enhanced chemical vapor deposition process is approximately 3,000 W, and provides a power density of approximately 4 W/cm² for a 300 mm diameter wafer. In contrast, microwave modules according to embodiments may use a 300 W power amplifier with a 4 cm diameter applicator, to provide a power density of approximately 24 W/cm².

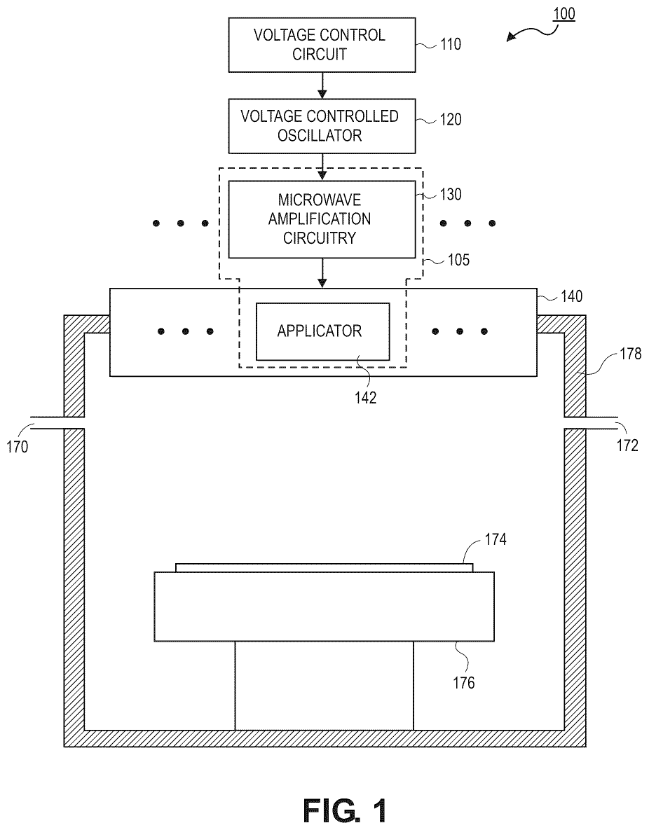

Referring now to FIG. 1, a cross-sectional illustration of a processing tool 100 is shown, according to an embodiment. The processing tool 100 may be a processing tool suitable for any type of processing operation that utilizes a plasma. For example, the plasma processing tool 100 may be a processing tool used for plasma enhanced chemical vapor deposition (PECVD), plasma enhanced atomic layer deposition (PEALD), etch and selective removal, and plasma cleaning. While the embodiments described in detail herein are directed to plasma processing tools, it is to be appreciated that additional embodiments may include a processing tool 100 that include any tool that utilizes microwave radiation. For example, a processing tool 100 that utilizes microwave radiation without needing the formation of a plasma may include industrial heating and/or curing processing tools 100.

Generally, embodiments include a processing tool 100 that includes a chamber 178. In processing tools 178 that are used for plasma processing, the chamber 178 may be a vacuum chamber. A vacuum chamber may include a pump (not shown) for removing gases from the chamber to provide the desired vacuum. Additional embodiments may include a chamber 178 that includes one or more gas lines 170 for providing processing gasses into the chamber 178 and exhaust lines 172 for removing byproducts from the chamber 178. While not shown, it is to be appreciated that the processing tool may include a showerhead for evenly distributing the processing gases over a substrate 174.

In an embodiment, the substrate 174 may be supported on a chuck 176. For example, the chuck 176 may be any suitable chuck, such as an electrostatic chuck. The chuck may also include cooling lines and/or a heater to provide temperature control to the substrate 174 during processing. Due to the modular configuration of the microwave modules described herein, embodiments allow for the processing tool 100 to accommodate any sized substrate 174. For example, the substrate 174 may be a semiconductor wafer (e.g., 200 mm, 300 mm, 450 mm, or larger). Alternative embodiments also include substrates 174 other than semiconductor wafers. For example, embodiments may include a processing tool 100 configured for processing glass substrates, (e.g., for display technologies).

According to an embodiment, the processing tool 100 includes one or more modular microwave sources 105. The modular microwave source 105 may include solid state microwave amplification circuitry 130 and an applicator 142. In an embodiment, a voltage control circuit 110 provides an input voltage to a voltage controlled oscillator 120 in order to produce microwave radiation at a desired frequency that is transmitted to the solid state microwave amplification circuitry 130 in each modular microwave source 105. After processing by the microwave amplification circuitry 130, the microwave radiation is transmitted to the applicator 142. According to an embodiment, an array 140 of applicators 142 are coupled to the chamber 178 and each function as an antenna for coupling the microwave radiation to the processing gasses in the chamber 178 to produce a plasma.

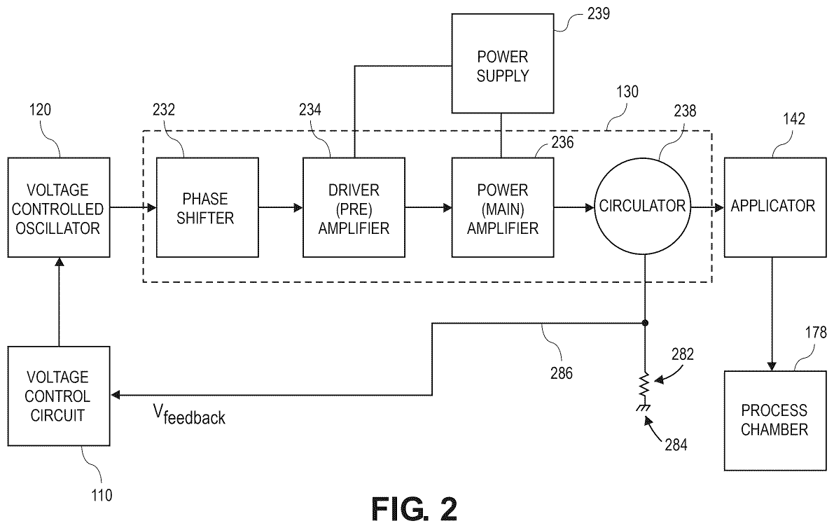

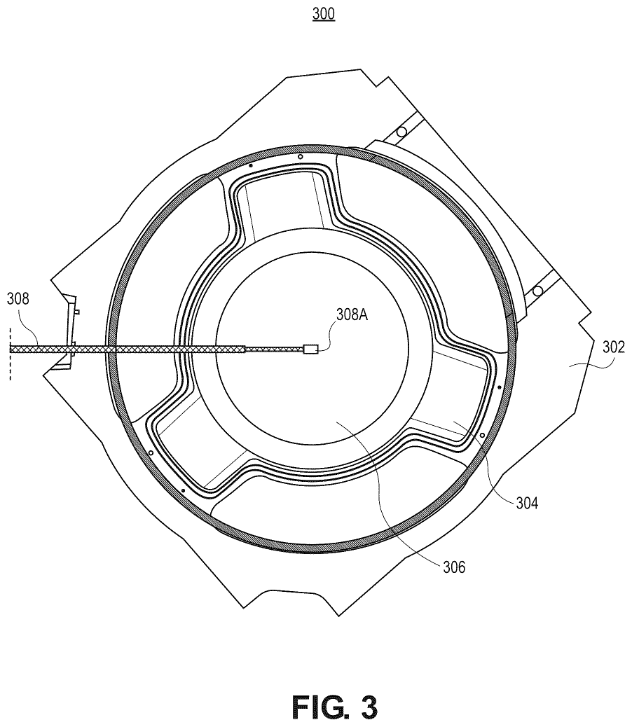

Referring now to FIG. 2, a schematic block diagram of the electronics in a modular microwave source is shown and described in greater detail, according to an embodiment. As described above, a voltage control circuit 110 provides an input voltage to a voltage controlled oscillator 120. Embodiments may include an input voltage between approximately 1V and 10V DC. The voltage controlled oscillator 120 is an electronic oscillator whose oscillation frequency is controlled by the input voltage. According to an embodiment, the input voltage from the voltage control circuit 110 results in the voltage controlled oscillator 120 oscillating at a desired frequency. In an embodiment, the microwave radiation may have a frequency between approximately 2.3 GHz and 2.6 GHz.

According to an embodiment, the microwave radiation is transmitted from the voltage controlled oscillator 120 to the microwave amplification circuitry 130. In the illustrated embodiment, a single instance of the microwave amplification circuitry 130 is shown. However, embodiments may include any number of instances of microwave amplification circuitry 130. Particularly, the number of instances of microwave amplification circuitry 130 may be equal to the number of applicators 142 needed in the array 140 of applicators 142. As such, each applicator 142 may be coupled to different instances of the microwave amplification circuitry 130 to provide individual control of the power supplied to each applicator 142. According to an embodiment, when more than one modular microwave source 105 is used in the process tool 100, the microwave amplification circuitry 130 may include a phase shifter 232. When only a single applicator is used, the phase shifter 232 may be omitted. The microwave amplification circuitry 130 may also include a driver/pre-amplifier 234, and a main microwave power amplifier 236 that are each coupled to a power supply 239. According to an embodiment, the microwave amplification circuitry 130 may operate in a pulse mode. For example, the microwave amplification circuitry 130 may have a duty cycle between 1% and 99%. In a more particular embodiment, the microwave amplification circuitry 130 may have a duty cycle between approximately 15% and 30%.

In an embodiment, the microwave radiation may be transmitted to the applicator 142 after being amplified. However, part of the power transmitted to the applicator 142 may be reflected back due to the mismatch in the output impedance. Accordingly, some embodiments also include a feedback line 286 that allows for the level of reflected power to be fed back to the voltage control circuit 110. The level of reflected power V_{feedback} may be directed to the feedback line 286 by using a circulator 238 between the power amplifier 236 and the applicator 142. The circulator 238 directs the reflected power to a dummy load 282 and ground 284, with the level of reflected power V_{feedback} being read prior to the dummy load 282. In an embodiment, the level of reflected power V_{feedback} may be used by the voltage control circuit 110 to adjust the output voltage that is sent to the voltage controlled oscillator 120, which in turn varies the output frequency of the microwave radiation that is transmitted to the microwave amplification circuitry 130. The presence of such a feedback loop allows for embodiments to provide continuous control of the input voltage of the voltage controlled oscillator 120, and allows for reductions in the level of reflected power V_{feedback}. In an embodiment, the feedback control of the voltage controlled oscillator 120 may allow for the level of the reflected power to be less than approximately 5% of the forward power. In some embodiments, the feedback control of the voltage controlled oscillator 120 may allow for the level of the reflected power to be less than approximately 2% of the forward power. Accordingly, embodiments allow for an increased percentage of the forward power to be coupled into the processing chamber 178, and increases the available power density coupled to the plasma. Furthermore, impedance tuning using a feedback line 286 is superior to impedance tuning in typical slot-plate antennas. In slot-plate antennas, the impedance tuning involves moving two dielectric slugs formed in the applicator. This involves mechanical motion of two separate components in the applicator, which increases the complexity of the applicator. Furthermore, the mechanical motion may not be as precise as the change in frequency that may be provided by a voltage controlled oscillator 120.

In an embodiment, a plasma probe for analyzing plasma characteristics is disclosed, e.g., for including in a chamber such as described above or in any suitable chamber for measuring a plasma formed therein. It is to be appreciated that plasma processing is a critical operation in the semiconductor industry, where techniques such as dry plasma etch, ion implementation and deposition are widely used. The quality and the uniformity of the plasma play a crucial role in determining the properties and characteristics of the material etched or deposited. In plasma etch, if the plasma is not uniform across the wafer, some area may be over-etched or under-etched, which can lead to variations in the feature dimensions. This can result in non-functional or unreliable devices, leading to a lower yield and higher manufacturing cost. Thus, it can be important to ensure a uniform plasma across the entire wafer to achieve a high yield and consistent device performance.

To achieve the desired performance and characteristics off all chips across a wafer - from center to edge, a uniform plasma across may be required across a wafer from center to edge. There are many “tuning knobs” in modern plasma reactors, by which plasma radial profile could be adjusted, but mostly those “knobs” crosstalk to each other and do not have straightforward impact on common plasma uniformity issues, for instance, plasma density center peak high. To understand a “tuning knob” effect, researchers could verify “on wafer” parameters after plasma treatment, but this approach can be highly time and resource consuming, and cannot be done in “real time.” In an embodiment, plasma probe measurements are implemented to provide “real time” plasma diagnostics.

As an exemplary implementation of a resonator probe in a plasma chamber, FIG. 3 illustrates a plan view of a resonator probe inserted into a plasma processing region of a plasma processing chamber, in accordance with an embodiment of the present disclosure.

Referring to FIG. 3, a plasma processing apparatus 300 includes a chamber 302 with an inner chamber wall. A workpiece support 304 is within the inner chamber wall and is for supporting a workpiece 306 in a processing region of the chamber 302. A resonator probe 308 extends through the chamber 302 and inner chamber wall and into a plasma region above the workpiece 306. The resonator probe 308 has a probe tip 308A which, in one embodiment, is suspended over a center of the workpiece 306.

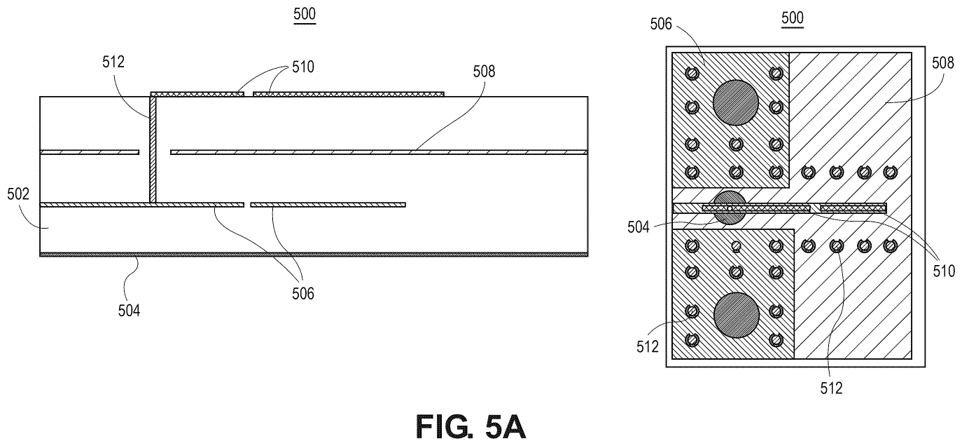

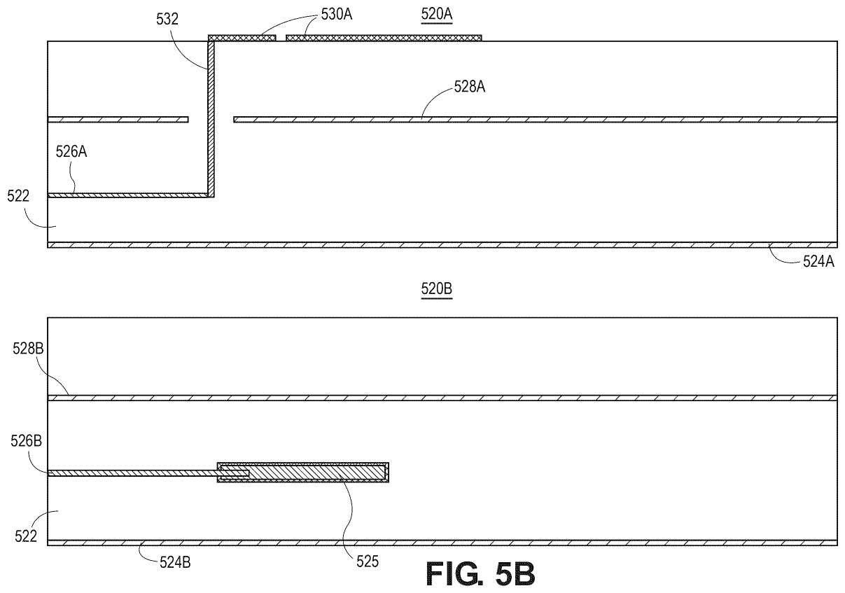

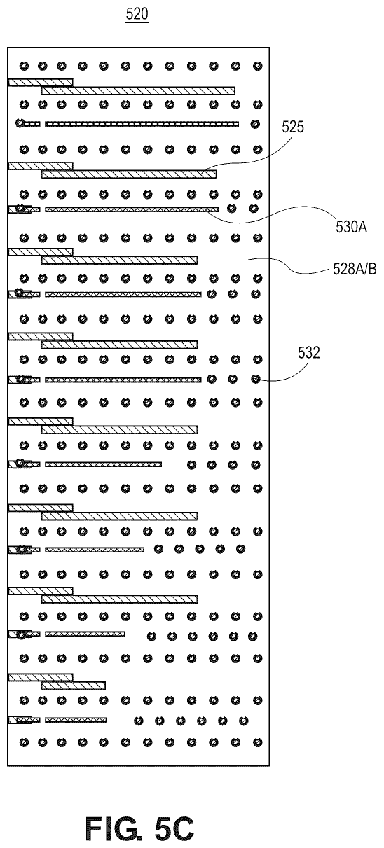

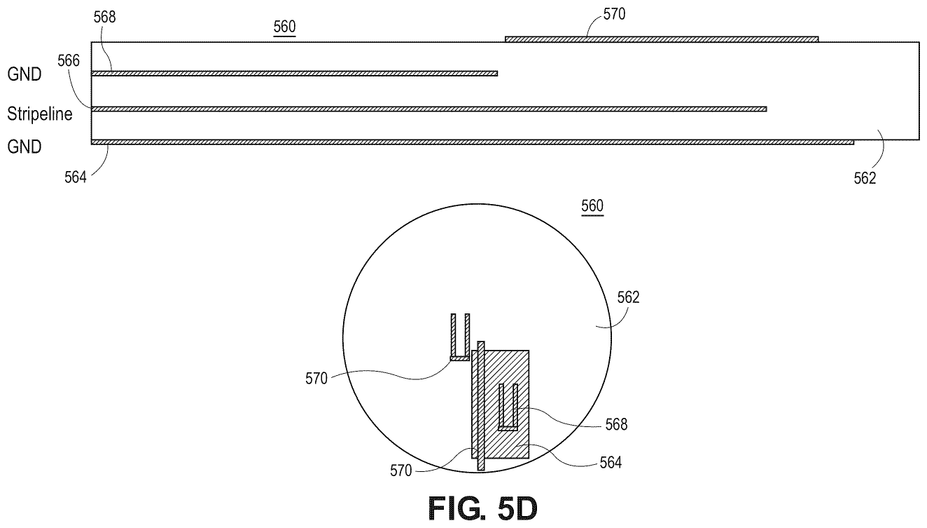

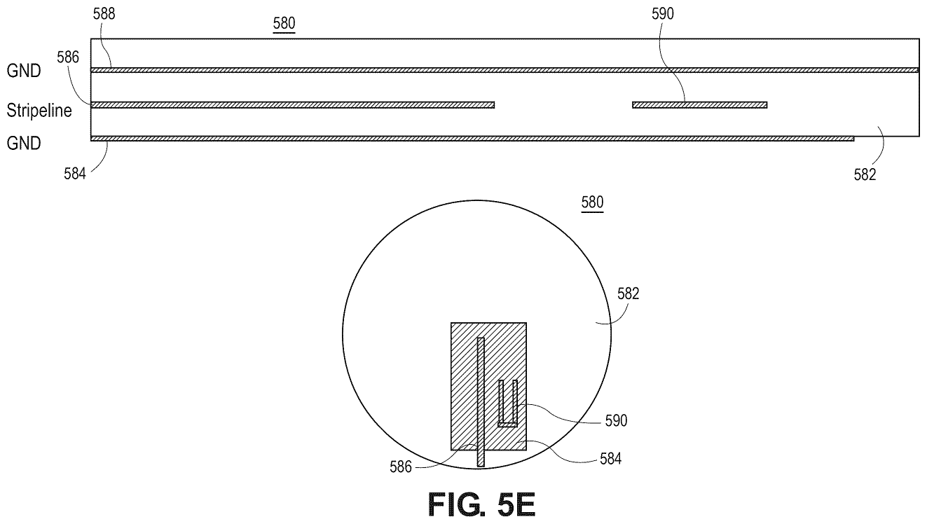

In an embodiment, the resonator probe 308 is configured to measure temperature. In an embodiment, the resonator probe 308 has a structure such as described below in association with FIGS. 5A-5E. In other embodiments, the resonator probe is flush with the interior wall of the chamber (or is behind the chamber wall). Such a sidewall-type implementation may be less perturbing than the penetrating probe shown.

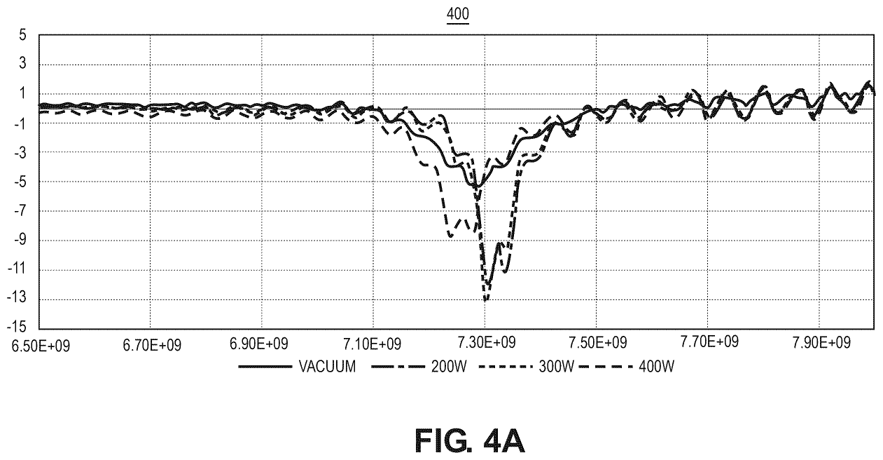

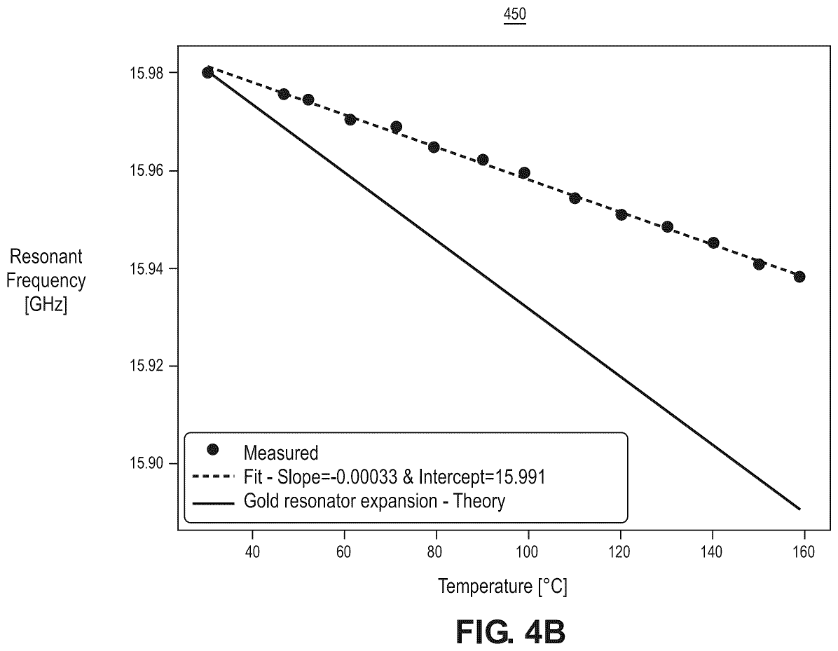

As exemplary data obtained using probes described herein, FIG. 4A is a plot 400 of microwave source plasma measurements as a function of Watts (W), and FIG. 4B is a plot 450 of resonant frequency as a function of temperature (showing a temperature dependence), in accordance with an embodiment of the present disclosure.

As exemplary resonator probes for including in a plasma processing region, FIGS. 5A-5E illustrate cross-sectional views and plan views of resonator probes or wafers for use in a plasma processing region of a plasma processing chamber, in accordance with an embodiment of the present disclosure.

Regarding an exemplary probe, FIG. 5A illustrates a cross-sectional view (left-hand side) and a plan view (right-hand side) of a resonator probe 500. The resonator probe 500 includes a substrate 502 (such as a dielectric or semiconductor substrate), a buried resonator 506, a ground plane 508, an exposed resonator 510, and coupling vias 512. The resonator probe 500 can have a high nₑ design, and can take on a half-wave microstrip resonator coaxial form.

Regarding a first exemplary wafer, FIG. 5B illustrates cross-sectional views 520A and 520B, and FIG. 5C illustrates a plan view of a resonator wafer 520. The resonator wafer 520 includes a substrate 522 (such as a dielectric or semiconductor substrate), a buried resonator 526B, an exposed resonator 526A/530A, ground planes 524A/B and 528A/B, and coupling vias 532. The buried resonator 526B can have a resonator width that varies for overlap, such as is depicted.

Regarding a second exemplary wafer that only has exposed resonators, FIG. 5D illustrates a cross-sectional view (top) and a plan view (bottom) of a resonator wafer 560. The resonator wafer 560 includes a substrate 562 (such as a dielectric or semiconductor substrate), ground lines 564 and 568, a stripline 566, and an exposed resonator 570.

Regarding a third exemplary wafer that only has buried resonators, FIG. 5E illustrates a cross-sectional view (top) and a plan view (bottom) of a resonator wafer 580. The resonator wafer 580 includes a substrate 582 (such as a dielectric or semiconductor substrate), ground lines 584 and 588, a stripline 586, and an exposed resonator 590.

In an embodiment, with reference again to the above exemplary resonator probes and resonator wafers, an exposed resonator has a first resonant frequency, and a buried resonator has a second resonant frequency, the second resonant frequency different than the first resonant frequency. In one embodiment, the second resonant frequency is greater than the first resonant frequency. In another embodiment, the second resonant frequency is less than the first resonant frequency.

In an embodiment, a workpiece processed in a plasma processing chamber can be or include any substrate that is commonly used in semiconductor manufacturing environments. For example, a workpiece may include a semiconductor wafer. In an embodiment, semiconductor materials may include, but are not limited to, silicon or III-V semiconductor materials. The semiconductor wafer may be a semiconductor-on-insulator (SOI) substrate in some embodiments. Typically, semiconductor wafers have standard dimensions, (e.g., 200 mm, 300 mm, 450 mm, or the like). However it is to be appreciated that the workpiece may have any dimension. Embodiments may also include workpieces that include non-semiconductor materials, such as glass or ceramic materials. In an embodiment, the workpiece may include circuitry or other structures manufactured using semiconductor processing equipment. In yet another embodiment, the workpiece may include a reticle or other lithography mask object.

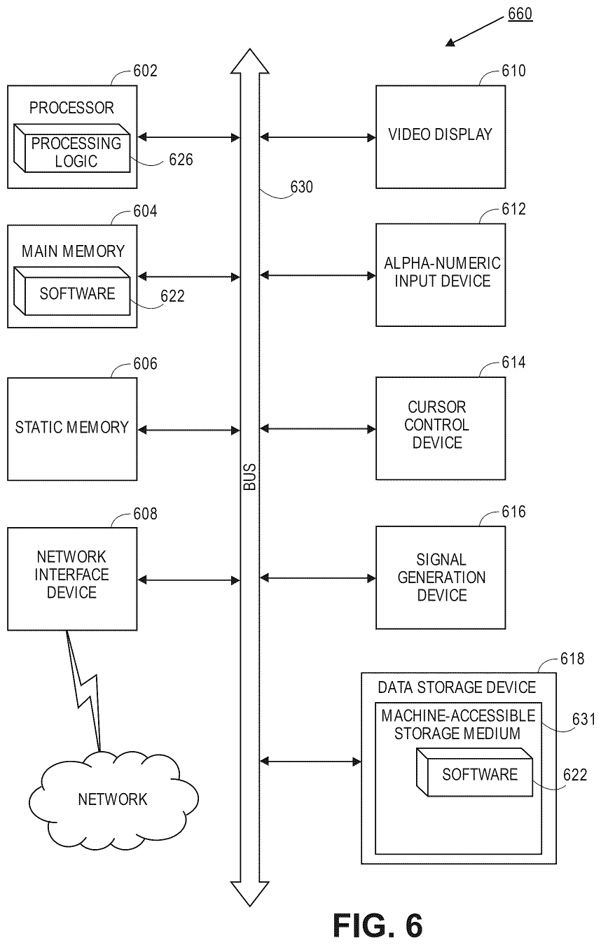

Referring now to FIG. 6, a block diagram of an exemplary computer system 660 of a processing tool, such as processing tool or chamber 300, is illustrated in accordance with an embodiment. In an embodiment, computer system 660 is coupled to and controls processing in the processing tool or chamber 300. In an embodiment, computer system 660 can process resonator probe measurements from resonator probes such as described in association with FIGS. 5A-5E. Computer system 660 may be connected (e.g., networked) to other machines in a Local Area Network (LAN), an intranet, an extranet, or the Internet. Computer system 660 may operate in the capacity of a server or a client machine in a client-server network environment, or as a peer machine in a peer-to-peer (or distributed) network environment. Computer system 660 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 660, the term “machine” shall also be taken to include any collection of machines (e.g., computers) that individually or jointly execute a set (or multiple sets) of instructions to perform any one or more of the methodologies described herein.

Computer system 660 may include a computer program product, or software 622, having a non-transitory machine-readable medium having stored thereon instructions, which may be used to program computer system 660 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 660 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 660 may further include a system network interface device 608 for communicating with other devices or machines. The computer system 660 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 631 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 660, the main memory 604 and the system processor 602 also constituting machine-readable storage media. The software 622 may further be transmitted or received over a network 620 via the system network interface device 608.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A plasma processing apparatus, comprising:
a chamber with an inner chamber wall;
a workpiece support within the inner chamber wall, the workpiece support for supporting a workpiece in a processing region of the chamber; and
a resonator probe coupled to the inner chamber wall, the resonator probe comprising an exposed resonator and a buried resonator.

2. The plasma processing apparatus of claim 1, wherein the exposed resonator has a first resonant frequency, and the buried resonator has a second resonant frequency, the second resonant frequency different than the first resonant frequency.

3. The plasma processing apparatus of claim 2, wherein the second resonant frequency is greater than the first resonant frequency.

4. The plasma processing apparatus of claim 2, wherein the second resonant frequency is less than the first resonant frequency.

5. The plasma processing apparatus of claim 1, wherein the resonator probe is configured to perform a temperature measurement.

6. The plasma processing apparatus of claim 5, wherein the temperature measurement comprises converting a measured microwave resonant frequency to a temperature value.

7. The plasma processing apparatus of claim 1, wherein the resonator probe is a printed resonator probe.

8. A resonator probe for measuring a temperature and a plasma property in a plasma region of a plasma processing apparatus, the resonator probe comprising:
an exposed resonator; and
a buried resonator.

9. The resonator probe of claim 8, wherein the exposed resonator has a first resonant frequency, and the buried resonator has a second resonant frequency, the second resonant frequency different than the first resonant frequency.

10. The resonator probe of claim 9, wherein the second resonant frequency is greater than the first resonant frequency.

11. The resonator probe of claim 9, wherein the second resonant frequency is less than the first resonant frequency.

12. The resonator probe of claim 8, wherein measuring the temperature comprises converting a measured microwave resonant frequency to a temperature value.

13. The resonator probe of claim 8, wherein the resonator probe is a printed resonator probe.

14. A method for monitoring a plasma parameter, the method comprising:
providing a resonator probe coupled to an inner chamber wall of a plasma processing apparatus, the resonator probe comprising an exposed resonator and a buried resonator;
measuring a temperature of the resonator probe; and
using the measured temperature to correct for temperature effects that can inhibit the measurement of plasma properties.

15. The method of claim 14, wherein the exposed resonator has a first resonant frequency, and the buried resonator has a second resonant frequency, the second resonant frequency different than the first resonant frequency.

16. The method of claim 15, wherein the second resonant frequency is greater than the first resonant frequency.

17. The method of claim 15, wherein the second resonant frequency is less than the first resonant frequency.

18. The method of claim 14, wherein measuring the temperature of the plasma in the plasma processing apparatus comprises converting a measured microwave resonant frequency to a temperature value.

19. The method of claim 14, wherein the resonator probe is a printed resonator probe.

20. The method of claim 14, wherein measuring the temperature of resonator probe in the plasma processing apparatus comprises measuring a temperature of a resonator probe used to measure a property of a pulsed plasma.
